(19) United States
(12) Patent Application Publication
(10) Pub. No.: US 2018/0321304 A1
(43) Pub. Date: Nov. 8, 2018

(54) APPARATUS AND METHOD FOR PERFORMING AVALANCHE MODE DELTA VSD TESTING

(71) Applicant: Integrated Technology Corporation, Tempe, AZ (US)

(72) Inventors: Steven T. Clauter, Goodyear, AZ (US); Ausin Hsu, Chandler, AZ (US); Gary B. Rogers, Mesa, AZ (US); Bradley Thomas Wolford, Scottsdale, AZ (US)

(21) Appl. No.: 15/587,696

(22) Filed: May 5, 2017

(51) Int. Cl. G01R 31/28; G01R 31/27; G01R 31/26

(52) U.S. Cl. CPC G01R 31/2849; G01R 31/2628; G01R 31/2839; G01R 31/27

(57) ABSTRACT

A device and method for performing Avalanche Mode Delta Vs_{D} testing of a semiconductor device under test (DUT), include a current source configured to provide energy in the form of a substantially non-decaying current to a DUT for heating of the DUT during an avalanche mode; and test circuitry electrically couplable to the current source and the DUT and configured to perform Avalanche Mode Delta Vs_{D} testing of the DUT.

### FIELD OF DISCLOSURE

The present disclosure relates generally to an apparatus for performing die bond testing of a semiconductor device under test (DUT), and more particularly, to a method and apparatus for performing Delta Vs_{D} testing using Avalanche Mode for heating of the DUT.

### BACKGROUND

Typically, semiconductor devices undergo many series of fabrication processes such as deposition, removal, patterning and modification of electrical properties (e.g., doping, annealing, and ultraviolet processing). Upon fabrication, the chips or dies on the wafer are tested for their functionality, capacity or integrity. The dies, which have passed the post-fabrication test, are packaged. The packaged dies undergo post-packaging testing to determine whether the dies have been packaged properly or whether the dies have sustained any damages during packaging.

Power semiconductor devices (e.g., MOSFETs, IGBTs or other semiconductor devices) are designed to withstand a specified level of power dissipation. Thus, the power semiconductor devices are tested for power handling capacity. In order to determine power handling capacity of the power semiconductor devices, die attach characteristics (e.g., thermal response) of power semiconductor devices under test (DUT) are obtained.

Delta V_{SD} testing can be used to check for die bond integrity of packaged power semiconductor devices in a given lot or a group of the same type of DUTs. In general, a thermal response of the die can be determined by obtaining a change in forward voltage drop of a reference junction (e.g., the body diode) of a DUT before and after heating of the DUT. A reference junction of the body diode of a power semiconductor is a junction, which exhibits more sensitivity to temperature than other junctions of the DUT. Thus, the reference junction can function as a temperature sensor of the DUT. For example, a reference junction of a power MOSFET is generally a junction at which the source to drain voltage (Vs_{D}) of the body diode of the MOSFET can be measured.

In order to obtain the thermal response of a DUT, a forward voltage drop of the reference junction of the DUT is measured at an ambient state (hereinafter, also referred to as the “Initial” source drain voltage in millivolts, or V_{SDi} as per MIL-STD-750E, Method 3161.1) prior to heating of the DUT. Then, the DUT is heated typically using a linear mode of operation by the DUT. After the heating, the forward voltage drop of the DUT is measured again at a steady state (hereinafter, also referred to as the “Final” source drain voltage in millivolts, or V_{SDf}). Thereafter, a change in the forward voltage drop of the DUT is obtained by subtracting the Initial measurement from the Final measurement of the DUT. Delta Vs_{D} is this change in the forward voltage drop of the diode junction of the DUT. Hence, such testing to obtain the thermal response of the DUT is referred to by some as Delta Vs_{D} testing.

Typically, when a power MOSFET (also referred to as a DUT) is Delta Vs_{D} tested, a Vs_{SD} tester includes a power supply and an analog control circuit. During the testing, the current in the DUT (e.g., energy supply for testing) is ramped up to a required level by biasing the DUT into conduction in a linear mode. The DUT then sees a large power dissipation, i.e., the drain voltage (V_{DS}) of the DUT multiplied by forward current (I_{D}s). This large power dissipation provides for the heating necessary to stress the die bond thermal transfer characteristics.

### SUMMARY

Conventional Delta Vs_{D} testing requires the DUT to operate in a linear mode at a fixed current for heating of the DUT. Conventional operation in a linear mode provides the power dissipation necessary for heating of the DUT. However, the linear mode operation of the DUT must be carefully controlled by an active feedback control loop in order to produce repeatable, and specified, test results. Any variation in either DUT current, I_{DS}, or DUT voltage, V_{DS}, will directly affect the power dissipation and, therefore, the Delta V_{SD} test results. In addition, there is a problem with the DUT current being concentrated in areas of the DUT that have the highest gain, or transconductance, which results in an uneven distribution of power dissipation. It should be further noted that the DUT's gain is temperature sensitive, leading to variations in DUT current and voltage, and henceforth, DUT power dissipation, which directly affects Delta V_{SD} test results.

Further, in such conventional linear mode Delta Vs_{D} testing, the stability of the active control loop must be taken into account. The control circuit performing the active closed-loop feedback control measures the current flow in the DUT and adjusts the gate bias to maintain the current flow at a required level. Since the linear mode of heating is affected by loop gain, transfer curves, threshold, and gate charge, the gate must be carefully biased, and thus, is often overcompensated to avoid any current overshoot or oscillations. Hence, the control loop adjusts the current slowly as the DUT is biased ON and the current is ramped up. Thus, a “one size fits all” method to deal with issues pertaining to the closed-loop feedback control and the operation in a linear mode becomes difficult to achieve.

As is described further below, in accordance with this disclosure, optimal Delta V_{SD} test results will be achieved with consistent power dissipation in the DUT using stable current and voltage pulses in all conditions. Such a stable mode occurs by placing the DUT into Avalanche Mode. In this condition, the DUT is driven with a specified, rectangular, or nearly rectangular, current pulse produced by a current source. This I_{H} heating pulse forces the DUT into Avalanche Mode whereby the DUT voltage, V_{DS}, rises quickly to a stable and predictable voltage level which then results in DUT power dissipation. The DUT heating during the Avalanche Mode also is much more rapid and evenly distributed than using the linear mode method since there is no control loop, or temperature dependent parameters, involved in Avalanche Mode. The amount of DUT heating can be easily specified by the I_{H} current source and the amount of Heating Time, t_{H}, when the current source is active as shown in the MIL-STD-750E, Method 3161.1. It should be noted that, unlike Avalanche Testing using Method 3470 which uses a triangular shaped current during Avalanche Testing, Avalanche Mode Delta V_{SD} testing uses a stable, rectangular, or nearly rectangular, current pulse as I_{H}.

One aspect of this disclosure relates to a device for performing Avalanche Mode Delta V_{SD} testing of a semiconductor device under test (DUT), including a current source configured to provide energy in the form of a substantially non-decaying current to a DUT for heating of the DUT during an avalanche mode; and test circuitry electrically couplable to the current source and the DUT and configured to perform Avalanche Mode Delta Vs_{D} testing of the DUT.

Optionally, the current source has energy storage capacity sufficient to supply an amount of current sufficient to drive the DUT into an avalanche mode and supply current to the DUT in a substantially non-decaying form for heating of the DUT during the avalanche mode.

Optionally, the current source is configured to be quickly turned on and off by opening and closing, respectively, of a switching element which electrically connects the current source and the test circuitry.

Optionally, the test circuitry includes a measurement current source configured to supply current I_{M} for creating the forward voltage drop of a junction of the DUT, and a voltage measurement device for measuring the forward voltage drop of the junction of the DUT.

Optionally, the test circuitry includes a measurement current source configured to supply current I_{M} for measuring forward voltage drop of a junction of the DUT, and a voltage measurement device for measuring the forward voltage drop of the junction of the DUT.

Optionally, a control is operably connected to the current source and the test circuitry, and configured to control operation of the device during Avalanche Mode Delta Vs_{D} testing.

Optionally, the measurement of the forward voltage drop of the junction of the DUT includes an initial, ambient state measurement, termed Vs_{Di}, of the forward voltage drop of the junction of the DUT made prior to heating of the DUT, and a final measurement, termed Vs_{Df}, made at a final steady state condition reached after the specified amount of energy has been delivered to the DUT during Avalanche Mode.

Optionally, the measurement of the forward voltage drop of the junction of the DUT includes an initial, ambient state measurement, termed Vs_{Di}, of the forward voltage drop of the junction of the DUT made prior to heating of the DUT, and a final measurement, termed Vs_{Df}, made after the specified time t_{H} for heating has expired during the avalanche mode.

Optionally, the voltage measurement device measures voltage supplied to the DUT during the Avalanche Mode Delta V_{SD} testing, the voltage including drain to source voltage of the DUT and the forward voltage drop of the junction of the DUT.

Optionally, the control causes a gate of the DUT to be biased off when the DUT enters into the avalanche mode, thereby preventing instability and oscillations which can occur when a linear mode of operation is used for heating of the DUT.

Optionally, the control causes the avalanche mode to be interrupted by opening a switching element configured to electrically couple the current source and the test circuitry.

Optionally, the control causes the current source to be quickly turned on and off by closing and opening, respectively, of the switching element.

Optionally, the control causes heating period t_{H} of the DUT to be controlled by opening the switching element.

Optionally, the opening of the switching element reduces the measurement time delay t_{MD} which occur after termination of the avalanche mode so that the V_{SD} can assume a value which corresponds to the temperature of the die at that point in time.

Optionally, the opening of the switching element reduces a measurement time delay t_{MD} which occur after termination of the avalanche mode and up to the point in time where V_{SD} corresponds to the temperature of a die of the DUT.

Another aspect relates to a method for performing testing of a power semiconductor device under test (DUT), the method including driving a DUT using an Avalanche Mode for heating of the DUT, and then performing a Delta V_{SD} testing of the DUT.

Optionally, the method further includes interrupting the avalanche mode for heating of the DUT by quickly turning on and off a current source for supplying heating current to the DUT during the avalanche mode.

Optionally, the method further includes providing a fast-cut off of the DUT from the current source; reducing a measurement time delay required for reaching a steady state for measuring a forward voltage drop of a junction of the die after heating of the DUT; and increasing accuracy of a measurement of the forward voltage drop of the junction of the die at a steady state reached after the heating of the DUT by reducing the measurement time delay.

Optionally, interrupting of the avalanche mode is performed by opening a switching element configured to electrically couple the current source and test circuit including the DUT.

Optionally, opening the switching element controls level of heating current I_{H} supplied from the current source during the avalanche mode and heating period t_{H}.

Optionally, opening the switching element controls heating current I_{H} supplied from the current source during the avalanche mode during heating period t_{H}.

Optionally, controlling the level of the heating current and the heating period reduces measurement time delay t_{MD} which occurs after a lapse of the heating period and during a period up to reaching the point where the V_{SDf} corresponds to the temperature of the die at that moment in time.

Optionally, controlling the level of the heating current and the heating period reduces measurement time delay T_{MD} which occurs after a lapse of the heating period and at time at which V_{SD} corresponds to the temperature of the die of the DUT.

These and further features of the present disclosure will be apparent with reference to the following description and attached drawings. In the description and drawings, particular embodiments of the present disclosure have been presented in detail as being indicative of some of the ways in which the principles of the disclosure may be employed, but it is understood that the disclosure is not limited correspondingly in scope. Rather, the disclosure includes all changes, modifications and equivalents coming within the scope of the claims appended hereto.

Features that are described and/or illustrated with respect to one embodiment may be used in the same way or in a similar way in one or more other embodiments and/or in combination with or instead of the features of the other embodiments.

### BRIEF DESCRIPTION OF THE DRAWINGS

In the annexed drawings:

FIG. 1 is a schematic circuit diagram of an embodiment of an exemplary device for performing Avalanche Mode Delta Vs_{D} testing of a power semiconductor device under test (DUT) in accordance with the present disclosure.

FIG. 2 depicts exemplary waveforms resulting from operation of the device of FIG. 1 for performing Avalanche Mode Delta Vs_{D} testing of a power semiconductor device under test (DUT) in accordance with the present disclosure.

FIG. 3 is a flow chart depicting the steps of an exemplary method for Avalanche Mode Delta Vs_{D} testing using the device of FIG. 1.

### DESCRIPTION

The embodiments of the present disclosure allow Avalanche Mode Delta Vs_{D} testing to be performed on a power semiconductor device under test (DUT) using an avalanche mode for heating the DUT, instead of using a linear operation mode required by conventional Delta Vs_{D} testing. Removing the linear operation requirement for heating of the DUT alleviates time delays, oscillations and instability occurring as a result of an active closed-loop feedback control. Moreover, muting, or masking, of differential heating of the DUT prone to occur in the linear mode can be also reduced, thereby reducing unreliable and inconsistent measurements. Therefore, Avalanche Mode Delta Vs_{D} testing in accordance with the present disclosure provides more reliable, consistent, and efficient test results as compared to the results obtained from typical Delta Vs_{D} testing performed using a linear mode for heating.

Referring, now, to the drawings, wherein like reference numerals refer to like parts in the several figures and wherein the illustrations are somewhat schematic and not necessarily to scale, but are presented to provide together with the description herein an understanding of various features of this disclosure, embodiments of the disclosure are described.

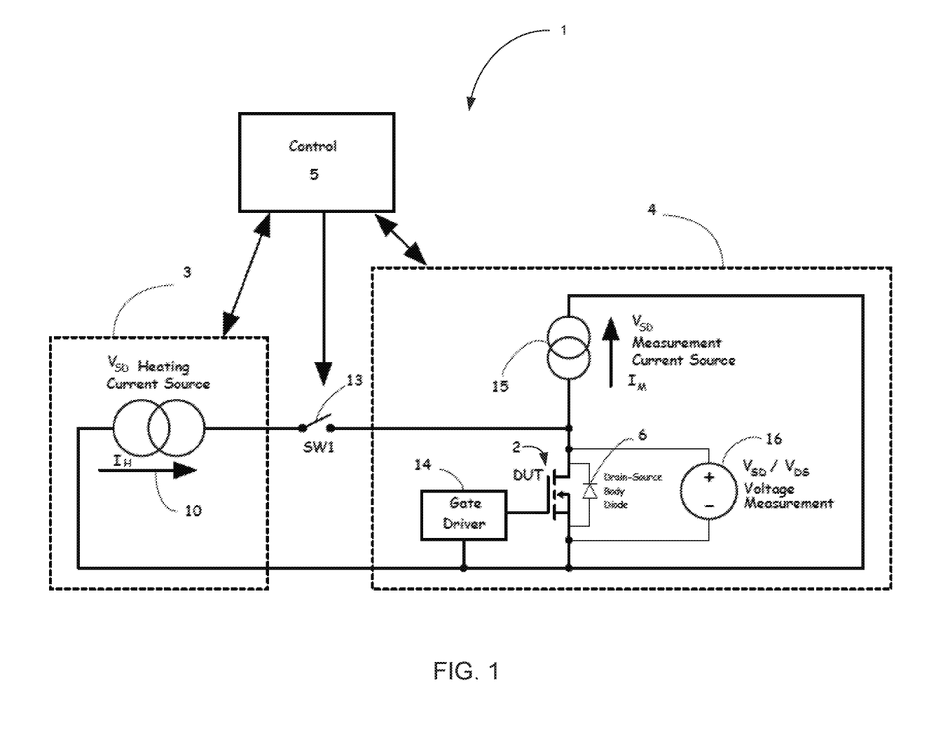

FIG. 1 is a schematic circuit diagram of an embodiment of an exemplary device 1 for performing Avalanche Mode Delta Vs_{D} testing of a semiconductor device under test (DUT) 2. The device 1 includes an energy supply 3, test circuitry 4 and a control 5. The energy supply 3 may be a current source 3, as shown, that supplies power to the test circuitry 4 for performing Avalanche Mode Delta Vs_{D} testing of a DUT 2. Sometimes herein such Avalanche Mode Delta V_{SD} testing is referred to as square pulse Delta V_{SD} testing.

The test circuitry 4 is electrically couplable to the current source 3 via a switching element SW1 13 (the switching element SW1 sometimes is referred to herein as switch or switching element together with the designation SW1 and/or reference numeral 13). When the switching element SW1 13 is in closed condition, the current source 3 supplies a constant heating current I_{H} to the DUT 2 during a heating period t_{H} for heating the DUT 2 using the Avalanche Mode. The test circuitry 4 includes the DUT 2, a gate driver 14, a measurement current source I_{M} 15, and a voltage measurement device 16. The gate driver 14 receives control information from the control 5 to keep the DUT 2 in the OFF condition during Avalanche Mode Delta Vs_{D} testing. Hence, the gate of the DUT 2 remains biased OFF at all times during the testing. The measurement current source I_{M} 15 provides current to turn on the body diode 6 of the DUT 2, e.g., to bias the body diode 6 to conduction, for measuring forward voltage drop of the body diode 6.

The control 5 is operatively coupled to the current source 3 and the test circuitry 4 for controlling the operation of the device 2. For example, the control 5 determines when to perform testing of the DUT 2, and controls the current source 3 to drive DUT 2 into Avalanche Mode at a specific current for a specific period of time. The control 5 may be, for example, a processor, memory and instructions stored in memory and executable by the processor plus other conventional input/output devices, logic circuitry, and so on, as will be evident to those having ordinary skill in the art. The control 5 may be local to the device 1 or may be remote from the device 1, e.g., operating from an external server or elsewhere. The switching element SW1 13 may be a high speed switch (HSS), which may be a single semiconductor device (e.g., MOSFET, IGBT, SCR, etc.) or one or more devices, which may switch on and off a current flow in the device 1. The switch may be operated, e.g., to be in open or closed condition, by the control 5.

When a Delta Vs_{D} test cycle of the DUT 2 begins, the control 5 causes the switching element SW1, 13 to close and the gate of the DUT 2 to be biased OFF.

Avalanche mode occurs when the reverse biased p-n junction of the DUT no longer blocks voltage from entering the p-n junction. Thus, voltage across the p-n junction increases. Thus, Avalanche Mode forces the highest rated voltage across a DUT. In addition, minority carriers are now able to enter the reverse biased p-n junction. Due to the increased voltage in the p-n junction, the p-n junction now has a high electric field. The high electric field accelerates the entered minority carriers to a velocity sufficient to collide with other minority carriers (i.e., bounded minority carriers) in the valance band. Due to the collisions, the bounded minority carriers become free and form more mobile electron-hole pairs (i.e., charge carriers). The charge carriers, in turn, increase the current in the p-n junction. The high electric field in the p-n junction accelerates the mobile electron-hole pairs, which collide with other bounded minority carriers. The collisions result in more freed minority carriers. The freed minority carriers create more and more mobile electron-hole pairs, resembling e.g., an avalanche of gases. Henceforth came the name “avalanche mode.” The increased current created by the charge carriers and the highest rated voltage in the p-n junction during the Avalanche Mode increase the power to a very high level. The increased power causes increased heat dissipation. The increased heat dissipation, in turn, provides the rapid rising and high heat necessary for heating of the DUT 2 for Avalanche Mode Delta Vs_{D} testing. Further, because the DUT 2 is in a condition of maximum Drain-to-Source Voltage, Avalanche Mode Delta Vs_{D} testing allows even higher heating of the DUT at lower current levels as compared to when a linear mode of operation is used for heating the DUT in conventional linear mode Delta Vs_{D} testing.

Avalanche Mode Delta Vs_{D} testing under the present disclosure dispenses with a linear mode of operation for heating used in conventional Delta Vs_{D} testing. Thus, square pulse Delta Vs_{D} testing avoids instability issues and oscillations occurring in the linear mode. The instability and oscillations occurring during the linear mode can be explained by using a power MOSFET as an example. When a MOSFET operates in a linear region, a minute increase in V_{G}s results in a large increase in I_{D}s. A large increase in I_{D}s results in a sudden increase in power dissipation over the DUT. However, in a linear mode of operation the power dissipation is not evenly distributed due to current concentrations in the higher gain sections of the DUT. Uneven distribution of heat over the DUT may mute the differential heating of the DUT required for Delta Vs_{D} testing. Muting of the differential heating, in turn, reduces temperature sensitivity required for Delta Vs_{D} testing. Reduction of temperature sensitivity may lead to inconsistent or unreliable Delta Vs_{D} measurements.

Conventional Delta Vs_{D} testing circuitry includes a power supply for the DUT and an analog control circuit, which creates a closed feedback loop from the drain junction of the DUT to the gate junction. During the linear mode the current and gain must be controlled in order to avoid thermal instability leading to destruction of the DUT. Hence, based on the current feedback, the control circuit adjusts the gate bias to maintain the current level during heating. Thus, the active closed-loop feedback control needs be compensated, or even overcompensated. The closed-loop feedback compensation is not easily accomplished since DUTs vary widely in gain, transfer curves, threshold, and gate charge and, in addition, adds considerably to measurement time delay, or t_{MD} when measuring the DUT's V_{SD} (source to drain voltage) of the body diode immediately after the heating portion of the test. Longer time delays allow the DUT to cool significantly after the test so the actual temperature of the DUT cannot be accurately measured.

Therefore, performing Delta Vs_{D} testing without requiring the DUT to operate in a linear mode may not only remove the issues pertaining to the linear mode of operation and the active closed-loop feedback control, but also may increase the accuracy and reliability of the test results since the measurement time delays t_{MD} (also referred to as settling delays) can be significantly reduced.

Referring back to FIG. 1, the heating period t_{H} can be controlled by controlling the current source 3 to be ON and OFF or by turning the switching element SW1 13 ON and OFF, or both. Hence, the Avalanche Mode of heating can be interrupted as desired.

Hence, Avalanche Mode Delta Vs_{D} testing expedites the testing by dispensing with a linear mode of operation requirement and the time expended to compensate for the active closed-loop control issues. Further, a fast cut-off of the DUT 2 from the current source 3 can be achieved by opening and closing of the switching element SW1 13. Such a fast cut-off allows the DUT 2 to interrupt Avalanche Mode quickly. The fast cut-off also reduces a settling delay (also referred to as measurement time delay t_{MD}) required to reach a steady state measurement current (also referred to as an I_{M}) in order to measure the forward voltage drop of the body diode 6 of the DUT 2. The shortened settling delay prevents overcooling of the DUT 2, thereby preserving the hot temperature of the body diode 6 of the DUT 2 necessary for making an accurate measurement. Hence, Avalanche Mode Delta Vs_{D} testing leads to faster, more accurate and efficient test results as compared to conventional Delta Vs_{D} testing.

The test circuitry 4 includes a DUT 2, a gate driver 14, a measurement current source I_{M} 15, and a voltage measurement device 16. The DUT 2 can be electrically coupled to the test circuitry 4 via a wire or a holding device, which receives the DUT 2 and electrically couples the DUT 2 to the test circuitry 4. The gate driver 14 is electrically coupled to a gate terminal of the DUT 2 for driving the DUT 2 OFF when Avalanche Mode Delta Vs_{D} testing begins. The gate of the DUT 2 remains OFF at all time during the testing.

The measurement current source I_{M} 15 supplies current to turn on or off the DUT 2 when a forward voltage drop Vs_{D} of the body diode 6 of the DUT 2 is measured by the voltage measurement device 16. The amount of current (hereinafter, also referred to as a measurement current I_{M}) supplied during voltage measurement(s) is a small amount (e.g., on the order of about 10 mA). That is, the amount of the I_{M} current should be sufficient to turn on the body diode of DUT 2, but should not cause unnecessary self-heating of the DUT 2.

The voltage measurement device 16 measures a forward voltage drop V_{SD} of the body diode 6 of the DUT 2 before and after performing Avalanche Mode Delta Vs_{D} testing of the DUT 2. The voltage measurement device 16 also measures the drain to source Voltage V_{DS} during the avalanche mode heating. Hence, the voltage measurement device 16 measures the voltage V_{DS} and V_{SD} in real time during the Avalanche Mode Delta V_{SD} testing. The real-time voltage measurements allow a user to control the heating period t_{H} of the DUT 2. Controlling the heating period t_{H} of the DUT 2, in turn, allows the user to provide a controlled heating of the DUT 2 during testing. A controlled heating includes releasing a sufficient amount of energy to stress the DUT 2 enough to obtain accurate V_{SD} measurements. The energy is typically defined as the amount of the power accumulated over the heating time t_{H}, i.e., power multiplied by time. The heating time t_{H} commences when the DUT 2 reaches the breakdown voltage. When the DUT 2 reaches the breakdown voltage, the DUT 2 enters into the Avalanche Mode. Hence, the time at which the voltage measurement device 16 measures the breakdown voltage indicates the beginning of the heating time t_{H}. Knowing the beginning of the heating time t_{H} allows the user to accurately determine when the heating time t_{H} should end. Hence, the voltage measurement device 16 allows the user to effectively control the heating time t_{H}.

It is noted that the thermal impedance (also referred to as thermal response) measurement described herein relates to such measurement of the DUTs from a same lot or a group of the same type of the DUTs. Thus, the thermal impedance measurement here is described with respect to obtaining a difference (Delta Vs_{D}) in the forward voltage drop of the reference junction of the DUT 2. However, MIL-STD-760E, Method 3161.1 may be referred to if it is desired to make specific temperature measurements and calculation of the transient junction to reference point thermal impedance.

The voltage measurement device 16 measures a forward voltage drop V_{SD} of the body diode 6 of the DUT 2 at an initial, ambient state (hereinafter, also referred to as the V_{SDi}, or Initial source drain voltage) in millivolts. When performing Avalanche Mode Delta Vs_{D} testing for a power semiconductor device, which is not a MOSFET, a forward voltage of a reference junction of that device under test should be made. In the ambient state, the switching element SW1 13 is in open condition. Hence, the test circuitry 4 is completely disconnected from the energy supply 3 of the device 1. The measurement current source I_{M} 15 supplies current to the body diode 6 of the DUT 2 for measuring the forward voltage drop of the body diode 6 of the DUT 2. Then, the initial measurement of the forward voltage drop of the body diode 6 of the DUT 2 is made without any possible interaction with the energy supply 3.

After making the initial Vs_{Di} measurement, the device 1 performs Avalanche Mode Delta Vs_{D} testing. The control 5 causes the switching element SW1 13 to close. The control 5 also causes the gate of the DUT 2 to be biased OFF. The current source 3 then drives the DUT 2 with the heating current I_{H}. The current source 3 will drive the DUT 2 almost immediately into Avalanche Mode and begin dissipating power. The heating period t_{H} can be controlled by disconnecting the DUT 2 from the current source 3 by opening the switching element SW1 13.

At the end of the heating period t_{H}, a few microseconds of delay after the switching element SW1 13 is opened are required until the voltage across DUT 2 drops to a low level. With a low voltage across the DUT 2, a second measurement (also referred to as a final measurement Vs_{Df}) of the forward voltage drop of the body diode 6 of the DUT 2 is made.

Delta Vs_{D} is obtained from subtracting the initial measurement Vs_{Di} from the final measurement Vs_{Df}. Based on the obtained Delta Vs_{D}, the thermal response of the DUT 2 is determined. The die integrity, in turn, is determined by comparing the thermal response of the DUT 2 to a thermal response of a known good DUT of the same type.

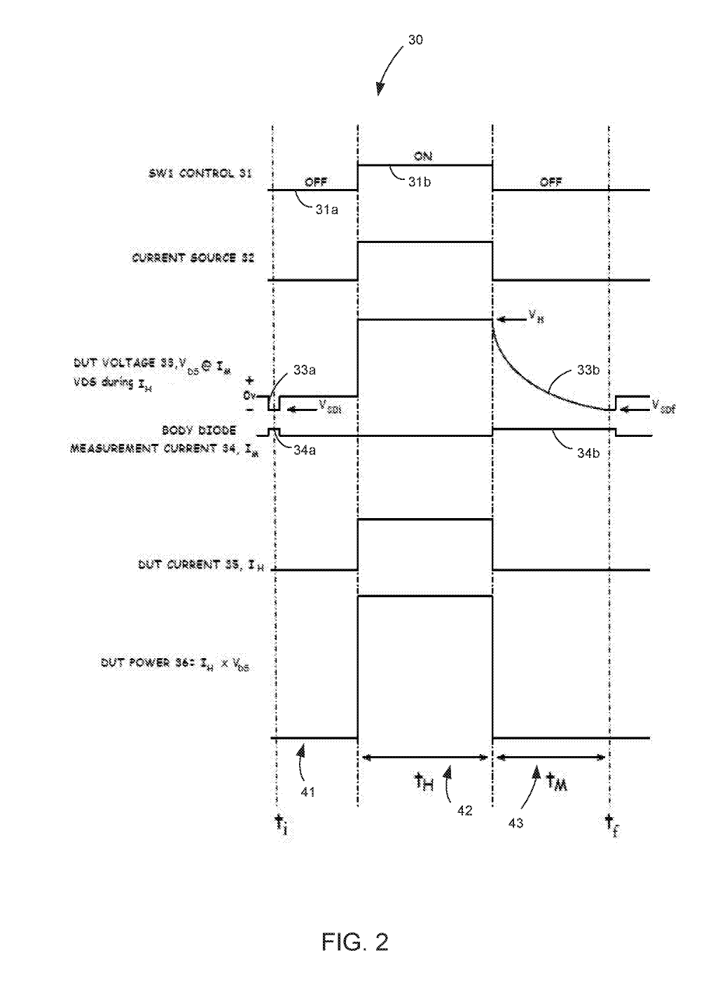

Referring to FIG. 2, a chart 30 shows a representation of signals, pulses, etc. that occur in the device 1 over a period of time or cycle in which Avalanche Mode Delta V_{SD} testing is carried out. One cycle is shown in the chart 30 from an initial time tᵢ until a final time t_{f}. The individual signals are shown over the cycle, and the horizontal axis of chart 30 going from left to right represents increasing time, i.e., initial time tᵢ is earlier than final time t_{f}. The respective signals 31-36 represent relatively low value (possibly zero) or relatively higher value, as shown at respective relatively lower or higher locations along the vertical direction of the drawing. Thus, for example, with respect to signal 31, which represents a signal from the control 5 to the switching element SW1 13 or may be considered an indication as to whether the switching element SW1 13 is open or closed, at portion 31a the signal from the control 5 is relatively low, which represents the switching element SW1 13 being open, i.e., OFF, so it does not provide current from the current source 3 to the test circuitry 4. Portion 31b of the signal 31 is relatively higher than portion 31a to represent that the control 5 provides a signal to cause the switching element SW1 13 to close, i.e., ON, to provide the heating current 10 I_{H} from the current source 3 to the test circuitry 4 to cause the DUT 2 to be driven into Avalanche Mode, as described herein.

In chart 30, three respective time intervals 41-43 are represented. Although the intervals 41-43 are shown as about the same length of time along the horizontal direction (axis) of the page to facilitate making the drawing, the actual lengths of time of the respective intervals may be very different from each other. Interval 41 is between the initial time tᵢ and the beginning of time t_{H}. Interval 42 (also labeled t_{H}) is the time during which the current source 3 is “turned on to the DUT 2,” e.g., the switching element SW1 13 is closed, to cause the voltage to rise across the DUT 2 until the DUT 2 goes into Avalanche Mode. Interval 43 (also labeled t_{M}) is the time interval (also referred to herein as the Measurement Time Delay t_{MD}) during which the DUT recovers from Avalanche Mode; this interval extends from the end of interval 42 t_{H} until the final time t_{f}. At the final time t_{f} the measurement current source 15 can again forward bias the body diode 6 of the DUT 2, and the final voltage measurement V_{SDf} may be taken—this would represent the “final” V_{SD} measurement.

Continuing to refer to FIG. 2, at initial time tᵢ, the control 5 causes the switching element SW1 13 to be open, as is represented at signal 31 (labeled SW1 control); and no current from current source 3 is provided to the test circuit 4, as is represented at signal 32 (labeled current source). During this time interval 41 the I_{M} current source 15 forward biases the body diode 6 of the DUT 2, and a voltage measurement, V_{SDi} is taken. This represents the “initial V_{SD} measurement.” Signal 34 represents the body diode 6 measurement current I_{M}. As is seen in signals 33 and 34 at the time tᵢ (at the beginning of interval 41) there is a dip 33a in the DUT voltage and there is a rise 34a in the body measurement current; these dip and rise represent the point at which the body diode measurement current I_{M} forward biases the body diode 6 so that the body diode voltage and, thus, the DUT drain to source voltage V_{DS} goes low, and V_{SDi} measurement is made by the V_{SD} voltage measurement device 16. Meanwhile, during the time interval 41, as is shown at signal 35, the DUT current, I_{H}, would be low, e.g., zero, as the control 5 causes the switching element SW1 13 to be open; and, as is shown at signal 36, the DUT power, which is the heating current I_{H} times the DUT voltage V_{DS}, is low, e.g., zero, as there is no heating current I_{H}.

Interval 42 is the heating interval t_{H}. Signals 31, 32, 33, 35 and 36 are high, as can be seen. Thus, control 5 causes the switching element SW1 13 to close, current I_{H} from the V_{SD} heating current source 3 (energy supply) is provided to the test circuit 4. The DUT voltage V_{DS} is high (this is the heating voltage V_{H} (signal 33)). During the time interval t_{H}, the current source 3 is turned on to the test circuit 4, and, more specifically to the DUT 2, which causes the voltage to rise across the DUT 2 until the DUT 2 goes into avalanche mode, at which point the voltage across the DUT 2 is at a maximum, which is represented at V_{H} in the signal 33. The V_{DS} 33 remains high and heating current I_{H} 32 continues to flow in the DUT 2, which dissipates power and increases the DUT's die temperature until either a specified time, such as when the heating time interval t_{H} (interval 42) has expired or the specified amount of power multiplied by time, thus, energy has been delivered into the DUT 2. Such amount of energy may be determined based on time or based on measurement. For example, as is represented by signals 33 and 35 multiplied together, the resulting DUT power signal represented by signal 36 is obtained. During the time interval t_{H} the V_{DS} is monitored, e.g., the voltage measurement device 16 continues to measure the V_{DS} during t_{H}.

Reference is made to the time interval 43, which represents the Measurement Delay time t_{M}. Signals 31, 32, 35 and 36 are low. Thus, the switching element SW1 13 is open so heating current source 3 no longer is providing the heating current I_{H} to the test circuit 4 or DUT 2, as is represented by DUT current signal 35 being low and the DUT power signal 36 being low. In addition, the DUT voltage V_{DS} decays exponentially as indicated by 33b during the Measurement Delay time t_{M}. At the same time, the measurement current source 15 (FIG. 1) starts to supply the measurement current I_{M} to the DUT 2 as indicated by a rise 34b. The measurement current I_{M} 34b then pulls the decaying DUT voltage V_{DS} down to V_{SDf}. V_{SDf} here indicates a final forward voltage drop of the body diode 6. Hence, during the time interval t_{M}, the Measurement Delay provides time for the DUT 2 to recover from Avalanche Mode. During this time interval, the voltage of the DUT 2 stabilizes to achieve the final V_{SD} measurement at time t_{f}.

At time t_{f} signals 31 through 36 remain low, as shown, except that in the DUT voltage, V_{SD}, of signal 33, and body diode measurement current, I_{M}, of signal 34. The DUT voltage V_{SD} remains at V_{SDf} for making the final measurement V_{SDf}. Further, the rise 34b in the measurement current I_{M} continues in order to keep the body diode 6 forward biased while the final measurement V_{SDf} is made. At time t_{f} the final V_{SDf} voltage is measured by the voltage measurement device 16. More specifically, after the DUT 2 has recovered from Avalanche Mode during the time interval t_{M}, the I_{M} measurement current source 15 can again forward bias the body diode 6 of the DUT 2, and another voltage measurement, V_{SDf}, can be taken. This represents the “final” V_{SD} measurement.

The difference between the initial and the final V_{SD} measurements can be computed, and this provides the Delta V_{SD} reading of die heating and, thereby, the quality of the die attach feature, parameter or characteristic of the DUT 2.

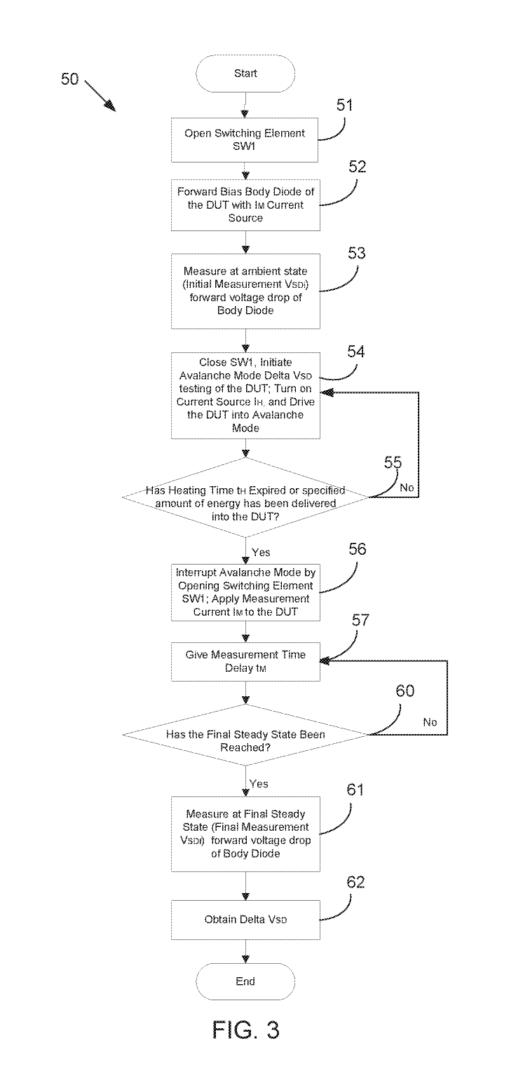

FIG. 3 is a flow chart depicting the steps of an exemplary method 50 for performing Avalanche Mode Delta Vs_{D} testing of a power semiconductor device (DUT) 2 in accordance with the present disclosure. The method 50 is described, using the device 1 of FIG. 1. However, the method may vary, depending on the type of a device under test (DUT) being tested and the type of switch used in the device 1.

The device 1 includes a current source 3, test circuitry 4 and a control 5. The current source is electrically couplable to the test circuitry 4 via a switching element SW1 13 and supplies power to the test circuitry 4 for performing Avalanche Mode Delta Vs_{D} testing of a DUT 2. When the switching element SW1 13 is in closed condition, the current source 3 supplies a constant heating current I_{H} to the DUT 2 during a heating period t_{H} for heating the DUT 2 using the Avalanche Mode. The test circuitry 4 includes the DUT 2, a gate driver 14, a measurement current source I_{M} 15, and a voltage measurement device 16. The gate driver 14 receives control information from the control 5 to keep the DUT 2 in the OFF condition during Avalanche Mode Delta Vs_{D} testing. The current source I_{M} 15 provides current to turn on the body diode 6 of the DUT 2, e.g., to bias the body diode 6 into conduction, for measuring forward voltage drop of the body diode 6 of the DUT 2. The control 5 is operatively coupled to the current source 3 and the test circuitry 4 for controlling the operation of the device 2 during the Avalanche Mode Delta Vs_{D} testing.

The method 50 begins at step 51 at which the control 5 causes the switching element SW1 13 to open. Thus, the current source 3 for supplying heating current I_{H} to the DUT 2 during the Avalanche Mode is disconnected from the test circuitry 4.

Upon opening of the switching element SW1 13, the method continues to step 52 at which the measurement current source I_{M} 15 supplies current to bias the body diode 6 of DUT 2 on. When the measurement current source I_{M} turns on the body diode 6 of DUT 2, the method moves to step 53 at which a forward voltage drop of the body diode 6 of DUT 2 is measured by the voltage measurement device 16 at an ambient state. This measurement of the voltage drop of the body diode 6 of DUT 2 may be referred to as the initial measurement Vs_{Di}.

After making the initial measurement Vs_{Di} the method 50 continues to step 54. At step 54, the control 5 causes the switching element SW1 13 to close, thereby initiating Delta V_{SD} testing of DUT 2. Upon closing the switching element SW1 13, the control 5 causes the gate of the DUT 2 to be biased off. The control 5 also causes the current source 3 to be turned on. The current source 3 then drives the DUT 2 with the heating current I_{H}. The current source 3 will drive the DUT 2 almost immediately into Avalanche Mode and begin dissipating power. The heating period t_{H} can be controlled by disconnecting the DUT 2 from the current source 3 by opening the switching element SW1 13.

The drain source voltage V_{DS} of the DUT 2 rises across the DUT 2 until the DUT 2 goes into Avalanche Mode. The DUT current los or I_{H} continues to flow, thereby resulting in dissipation of power and increase in the die temperature of the DUT 2 until a specified time (e.g., heating time t_{H}) has expired or a specified amount of power multiplied by time, or energy, has been delivered into the DUT 2. Thus, the method continues to step 55 at which whether the specified t_{H} has expired or the specified amount of energy has been delivered into the DUT 2 is determined. If, at step 55, it is determined that either the specified t_{H} has expired or the specified amount of energy has been delivered into the DUT 2, the method continues to step 56. If, however, at step 55, it is determined that neither the specified t_{H} has expired nor the specified amount of energy has been delivered into the DUT 2, the method reverts back to the step 54.

At step 56, the control 5 causes the switching element SW1 13 to open and interrupts the Avalanche Mode of the DUT 2. Also, the measurement current source 15 (FIG. 2) starts to supply the measurement current I_{M} to the DUT 2 and pulls down the DUT voltage V_{DS}. The method, then, continues to step 57 at which a few microseconds of delay (also referred to as the Measurement Delay time t_{MD}) after the switching element SW1 13 is caused to be in open condition are provided for the DUT 2 to reach a final steady state. During the Measurement Delay time t_{MD}, the measurement current source 15 continues to pull down the DUT voltage V_{DS} until V_{DS} decays to V_{SDf}. V_{SDf} indicates a final forward voltage drop of the body diode 6. The Measurement Delay time t_{MD} is given in order for the DUT 2 to recover from the Avalanche Mode and reach the final steady state so that the final measurement Vs_{Df} of the body diode 6 can be made. Hence, the method continues to step 60 at which it is determined whether the DUT 2 has reached the final steady state. If, at step 60, it is determined that the DUT 2 has indeed reached the final steady state, the method continues to step 61. If, at step 60, it is determined that the DUT 2 has not yet reached the final steady state, the method reverts back to step 57.

At step 61, a final measurement Vs_{Df} of the body diode 6 is made by the voltage measurement device 16. As was with the initial measurement Vs_{Di} the measurement current source I_{M} 15 supplies measurement current to the body diode 6 of the DUT 2 for measuring the final measurement Vs_{Df} of the body diode 6 of the DUT 2. Upon making the final measurement Vs_{Df} of the body diode 6, the method continues to step 62 at which Delta Vs_{SD} is obtained.

Delta Vs_{SD} is obtained from subtracting the initial measurement Vs_{Di} from the final measurement Vs_{Df}. Based on the obtained Delta Vs_{D}, the thermal response of the DUT 2 is determined. The die attach integrity, in turn, is determined by comparing the thermal response of the DUT 2 to a thermal response of a known good DUT of the same type. Then, the method ends.

Although the disclosure has been shown and described with respect to a certain embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the disclosure. In addition, while a particular feature of the disclosure may have been described above with respect to only one or more of several illustrated embodiments, such feature may be combined with one or more other features of the other embodiments, as may be desired and advantageous for any given or particular application.

What is claimed is:

1. A device for performing Avalanche Mode Delta Vs_{D} testing of a semiconductor device under test (DUT), comprising:
a current source configured to provide energy in the form of a substantially non-decaying current to a DUT for heating of the DUT during an avalanche mode; and
test circuitry electrically couplable to the current source and the DUT and configured to perform Avalanche Mode Delta Vs_{D} testing of the DUT.

2. The device of claim 1, wherein the current source has energy storage capacity sufficient to supply an amount of current sufficient to drive the DUT into an avalanche mode and supply current to the DUT in a substantially non-decaying form for heating of the DUT during the avalanche mode.

3. The device of claim 1, wherein the current source is configured to be quickly turned on and off by opening and closing, respectively, of a switching element which electrically connects the current source and the test circuitry.

4. The device of claim 1, wherein the test circuitry includes a measurement current source configured to supply current I_{M} for measuring forward voltage drop of a junction of the DUT, and a voltage measurement device for measuring the forward voltage drop of the junction of the DUT.

5. The device of claim 1, further comprising a control operably connected to the current source and the test circuitry, and configured to control operation of the device during Avalanche Mode Delta Vs_{D} testing.

6. The device of claim 4, wherein the measurement of the forward voltage drop of the junction of the DUT includes an initial, ambient state measurement, termed Vs_{Di}, of the forward voltage drop of the junction of the DUT made prior to heating of the DUT, and a final measurement, termed Vs_{Df}, made at a final steady state condition reached after the specified amount of energy has been delivered to the DUT during Avalanche Mode.

7. The device of claim 4, wherein the measurement of the forward voltage drop of the junction of the DUT includes an initial, ambient state measurement, termed Vs_{Di}, of the forward voltage drop of the junction of the DUT made prior to heating of the DUT, and a final measurement, termed Vs_{Df}, made after the specified time t_{H} for heating has expired during the avalanche mode.

8. The device of claim 4, wherein the voltage measurement device measures voltage supplied to the DUT during the Avalanche Mode Delta V_{SD} testing, the voltage including drain to source voltage of the DUT and the forward voltage drop of the junction of the DUT.

9. The device of claim 5, wherein the control causes a gate of the DUT to be biased off when the DUT enters into the avalanche mode, thereby preventing instability and oscillations which occur when a linear mode of operation is used for heating of the DUT.

10. The device of claim 5, wherein the control causes the avalanche mode to be interrupted by opening a switching element configured to electrically couple the current source and the test circuitry.

11. The device of claim 10, wherein the control causes the current source to be quickly turned on and off by closing and opening, respectively, of the switching element.

12. The device of claim 10, wherein the control causes heating period t_{H} of the DUT to be controlled by opening the switching element.

13. The device of claim 10, wherein the opening of the switching element reduces a measurement time delay t_{MD} which occur after termination of the avalanche mode and up to the point in time where V_{SD} corresponds to the temperature of a die of the DUT.

14. A method for performing testing of a power semiconductor device under test (DUT), the method comprising:
driving a DUT using an Avalanche Mode for heating of the DUT, and then performing a Delta V_{SD} testing of the DUT.

15. The method of claim 14, further comprising:
interrupting the avalanche mode for heating of the DUT by quickly turning on and off a current source for supplying heating current to the DUT during the avalanche mode.

16. The method of claim 15, further comprising:
providing a fast-cut off of the DUT from the current source;
reducing a measurement time delay required for reaching a steady state for measuring a forward voltage drop of a junction of the DUT after heating of the DUT; and
increasing accuracy of a measurement of the forward voltage drop of the junction of the DUT at a steady state reached after the heating of the DUT by reducing the measurement time delay.

17. The method of claim 15, wherein interrupting of the avalanche mode is performed by opening a switching element configured to electrically couple the current source and test circuit including the DUT.

18. The method of claim 17, wherein opening the switching element controls heating current I_{H} supplied from the current source during the avalanche mode during heating period t_{H}.

19. The method of claim 18, wherein controlling the level of the heating current and the heating period reduces measurement time delay t_{MD} which occurs after a lapse of the heating period and at time at which V_{SD} corresponds to the temperature of the die of the DUT.
